(19) United States
(12) Patent Application Publication
(10) Pub. No.: US 2011/0095397 A1
(43) Pub. Date: Apr. 28, 2011

(54) Semiconductor Structures Including Dielectric Layers and Capacitors Including Semiconductor Structures

(76) Inventors: Suk-jin Chung, Hwaseong-si (KR); Jae-hyoung Choi, Hwaseong-si (KR); Youn-soo Kim, Yongin-si (KR); Jae-soon Lim, Seoul (KR); Sang-yeol Kang, Seoul (KR)

(21) Appl. No.: 12/909,289

(22) Filed: Oct. 21, 2010

(30) Foreign Application Priority Data
Oct. 23, 2009 (KR) 10-2009-0101193

(51) Int. Cl. H01L 29/92; H01G 4/30

(52) U.S. Cl. 257/532; 361/301.4; 257/E29.342

(57) ABSTRACT

Semiconductor structures including a first conductive layer; a dielectric layer on the first conductive layer; a second conductive layer on the dielectric layer; and a crystallized seed layer in at least one of a first portion between the first conductive layer and the dielectric layer and a second portion between the dielectric layer and the second conductive layer. Related capacitors and methods are also provided herein.

### CLAIM OF PRIORITY

This application claims the benefit of Korean Patent Application No. 10-2009-0101193, filed Oct. 23, 2009, the contents of which are hereby incorporated herein by reference as if set forth in its entirety.

### FIELD

The present invention relates generally to semiconductor devices and, more particularly to, semiconductor structures including dielectric layers, capacitors including semiconductor structures, and methods of forming semiconductor structures.

### BACKGROUND

Dielectric layers used in semiconductor devices that are highly integrated and have a large capacity are typically very important. Dielectric layers may be provided between first and second conductive layers of a capacitor. Dielectric layers may also be provided between first and second conductive layers functioning as an electrode or used as a gate insulating layer. Furthermore, dielectric layers may be used for various purposes when semiconductor devices are fabricated.

For example, if a dielectric layer is provided between first and second conductive layers of a capacitor, the dielectric layer typically has a high dielectric constant in order to increase the capacitance of the capacitor. To increase the dielectric constant, the dielectric layer is typically crystallized. However, a high-temperature heat treatment process may be required to crystallize the dielectric layer. In addition, when a capacitor including the dielectric layer is driven, some amount of charge may leak through the dielectric layer disposed between first and second conductive layers of the capacitor.

### SUMMARY

Some embodiments of the present inventive concept provide a semiconductor structure including a first conductive layer; a dielectric layer on the first conductive layer; a second conductive layer on the dielectric layer; and a crystallized seed layer in at least one of a first portion between the first conductive layer and the dielectric layer and a second portion between the dielectric layer and the second conductive layer.

In further embodiments, the crystallized seed layer may be a niobium layer. The dielectric layer may be a tantalum oxide layer, a niobium oxide layer, or a composite layer including a tantalum oxide layer and a niobium oxide layer. When oxidized, the crystallized seed layer may have the same crystal structure as the dielectric layer.

In still further embodiments, the first conductive layer and the second conductive layer may include a metal nitride layer, a noble metal layer, a noble metal oxide layer, a metal silicide layer, an impurity-doped silicon layer, or a metal layer. At least one of the first conductive layer and the second conductive layer may be a metal nitride layer that has the same crystal structure as the dielectric layer. The first conductive layer or the second conductive layer may be a niobium nitride layer or a tantalum nitride layer.

Some embodiments provide a semiconductor structure including a first conductive layer including metal nitride; a dielectric layer on the first conductive layer including a tantalum oxide layer, a niobium oxide layer, or a composite layer including a tantalum oxide layer and a niobium oxide layer; and a second conductive layer on the dielectric layer including a metal nitride layer. A crystallized seed layer is formed in at least one of a first portion between the first conductive layer and the dielectric layer and a second portion between the dielectric layer and the second conductive layer. The crystallized seed layer includes a niobium layer.

Still further embodiments provide a capacitor including a first conductive layer; a dielectric layer on the first conductive layer; a second conductive layer on the dielectric layer; and a crystallized seed layer in at least one of a first portion between the first conductive layer and the dielectric layer and a second portion between the dielectric layer and the second conductive layer.

Some embodiments provide methods of forming a semiconductor structure, the method including forming a first conductive layer, forming a dielectric layer on the first conductive layer; forming a second conductive layer on the dielectric layer; and forming at least one of a first crystallized seed layer on the first conductive layer and a second crystallized seed layer on the dielectric layer.

In further embodiments, a heat treatment process for crystallizing the dielectric layer may be performed after the first crystallized seed layer, the dielectric layer, and the second crystallized seed layer are sequentially formed, or after the second conductive layer is formed. The dielectric layer may be a tantalum oxide layer, a niobium oxide layer, or a composite layer including a tantalum oxide layer and a niobium oxide layer. The crystallized seed layer may be a niobium layer.

### BRIEF DESCRIPTION OF THE DRAWINGS

FIG. 1 is a cross-section of a semiconductor structure according to some embodiments of the present general inventive concept.

FIG. 2 is a cross-section of a semiconductor structure according to some embodiments of the present general inventive concept.

FIG. 3 is a cross-section of a semiconductor structure according to some embodiments of the present general inventive concept.

Figure is a flowchart illustrating processing steps in the fabrication of semiconductor structures illustrated in FIG. 1 and processing steps for heat treating a dielectric layer according to some embodiments of the present inventive concept.

FIG. 5 is a flowchart illustrating processing steps in the fabrication of semiconductor structures illustrated in FIG. 2 and processing steps for heat treating a dielectric layer according to some embodiments of the present inventive concept.

FIG. 6 is a flowchart illustrating processing steps in the fabrication of semiconductor structures illustrated in FIG. 1 and processing steps for heat treating a dielectric layer according to some embodiments of the present inventive concept.

FIG. 7 is a flowchart illustrating processing steps in the fabrication of semiconductor structures illustrated in FIG. 2 and processing steps for heat treating a dielectric layer according to some embodiments of the present inventive concept.

FIG. 8 is a flowchart illustrating processing steps in the fabrication of semiconductor structures illustrated in FIG. 3 and processing steps for heat treating a dielectric layer according to some embodiments of the present general inventive concept.

FIG. 9 is a graph illustrating X-ray peaks to illustrate a degree of crystallinity of a dielectric layer according to a heat treatment temperature in accordance with some embodiments of the present inventive concept.

FIG. 10 is a graph illustrating X-ray peaks to illustrate a degree of crystallinity of a dielectric layer according to a first conductive layer at a constant heat treatment temperature in accordance with some embodiments.

FIG. 11 is a diagram of semiconductor devices including the semiconductor structure illustrated in FIG. 3 in accordance with some embodiments of the present inventive concept.

FIG. 12 is a circuit diagram of a unit cell of a dynamic random access memory (DRAM) device including a capacitor according to some embodiments of the present inventive concept.

FIG. 13 is a plan view of a memory module including a DRAM chip, according to some embodiments of the present inventive concept.

FIG. 14 is a block diagram of an electronic system including a DRAM chip according to some embodiments of the present inventive concept.

FIG. 15 is a block diagram of an electronic system including a logic chip according to some embodiments of the present inventive concept.

### DETAILED DESCRIPTION OF SOME EMBODIMENTS

The inventive concept now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present inventive concept are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Semiconductor structures according to some embodiments of the present inventive concept includes first and second, for example, top and bottom, conductive layers, a dielectric layer, and a crystallized seed layer, wherein the dielectric layer and the crystallized seed layer are provided between the first and second conductive layers. The crystallized seed layer may be formed on, under, or both on and under the dielectric layer. In some embodiments, the dielectric layer may be, for example, a tantalum oxide layer, a niobium oxide layer, or a composite layer including a tantalum oxide layer and a niobium oxide layer. The tantalum oxide layer may be represented by Ta₂O₅ or TaO. The niobium oxide layer may be represented by Nb₂O₅ or NbO. The crystallized seed layer may be a niobium layer.

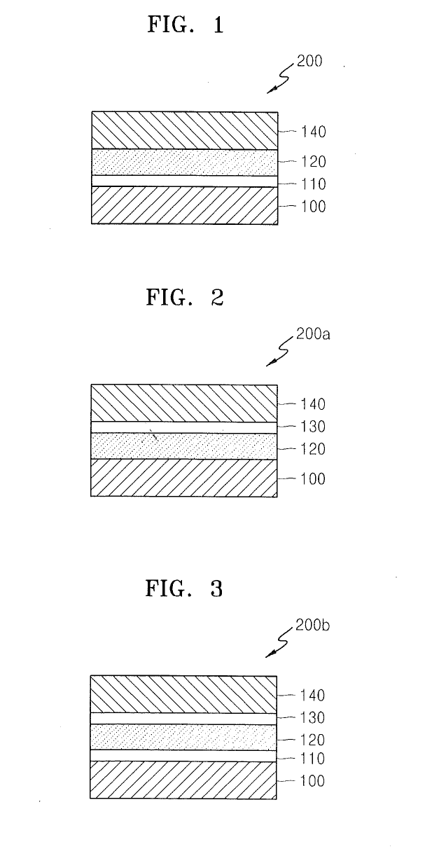

Semiconductor structures according to some embodiments may be used as, for example, a capacitor. The capacitor may be used in a semiconductor device, such as a dynamic random access memory (DRAM) device, a logic device, or the like. Various embodiments of the present general inventive concept will be discussed below with respect to FIGS. 1 through 15.

Various semiconductor structures will now be discussed in accordance with embodiments of the inventive concept with respect to FIGS. 1 through 3. Referring first to FIG. 1, a cross-section of semiconductor structure 200 in accordance with some embodiments of the present general inventive concept will be discussed. As illustrated in FIG. 1, the semiconductor structure 200 according includes a first conductive layer 100. The first conductive layer 100 may be any material layer having conductivity without departing from the scope of embodiments discussed herein. Thus, the first conductive layer 100 may be, for example, a metal nitride layer, a noble metal layer, a noble metal oxide layer, a metal silicide layer, an impurity-doped silicon layer, or a metal layer.

Examples of the metal nitride layer include a titanium nitride (TiN) layer, a tantalum nitride (TaN) layer, a niobium nitride (NbN) layer, a tungsten nitride (WN) layer, a titanium aluminum nitride (TiAlN) layer, a titanium silicon nitride (TiSiN) layer, a vanadium nitride (VN) layer, and a molybdium nitride (MoN) layer. Examples of the noble metal layer include a ruthenium layer Ru and a platinum layer Pt. Examples of the noble metal oxide layer include a ruthenium oxide layer and an iridium oxide layer. Examples of the metal silicide layer include a titanium silicide layer, a tungsten silicide layer, and a cobalt silicide layer. Examples of the metal layer include an aluminum layer, and a copper layer. However, the metal nitride layer, the noble metal layer, the noble metal oxide layer, the metal silicide layer, and the metal layer are not limited to the above examples.

A first crystallized seed layer 110 and a dielectric layer 120 may be sequentially provided on the first conductive layer 100. The first crystallized seed layer 110 may be formed in a first portion between the first conductive layer 100 and the dielectric layer 120. The first crystallized seed layer 110 may function as a seed for helping crystallization of the dielectric layer 120 of the semiconductor structure 200 when the dielectric layer 120 is heat treated. The first crystallized seed layer 110 may lower the crystallization temperature of the dielectric layer 120 in order to increase the dielectric constant of the dielectric layer 120. The dielectric layer 120 may be a tantalum oxide layer, a niobium oxide layer, or a composite layer including a tantalum oxide layer and a niobium oxide layer. When the crystallization temperature of the dielectric layer 120 is decreased, the dielectric constant of the dielectric layer 120 may be increased to 60 or more. When the dielectric layer 120 is a tantalum oxide layer, a niobium oxide layer, or a composite layer including a tantalum oxide layer and a niobium oxide layer, the dielectric layer 120 has a hexagonal crystal structure.

The first crystallized seed layer 110 may be a material layer that has a crystal structure similar to that of the dielectric layer 120 when oxidized to lower the crystallization temperature of the dielectric layer 120. For example, the first crystallized seed layer 110 may be a material layer having a hexagonal crystal structure, such as a niobium layer.

A second conductive layer 140 may be provided on the dielectric layer 120. The second conductive layer 140 and the first conductive layer 100 may include the same material. At least one of the first conductive layer 100 and the second conductive layer 140 may be a metal nitride layer having the same crystal structure as that of the dielectric layer 120 in order to increase the dielectric constant of the dielectric layer 120. For example, at least one of the first conductive layer 100 and the second conductive layer 140 may be a tantalum nitride layer (TaN) or a niobium nitride layer (NbN).

In some embodiments, the first conductive layer 100, the first crystallized seed layer 110, the dielectric layer 120, and the second conductive layer 140 may form a capacitor. The first crystallized seed layer 110 may be partially included in the dielectric layer 120 when the dielectric layer 120 is heat treated in the subsequent process.

Referring now to FIG. 2, a cross-section of a semiconductor structure 200a according to some embodiments of the present general inventive concept will be discussed. As illustrated in FIG. 2, the semiconductor structure 200a is similar to the semiconductor structure 200 of FIG. 1, except that the first crystallized seed layer 110 is not formed on the first conductive layer 100. Instead, a second crystallized seed layer 130 is formed on the dielectric layer 120.

The semiconductor structure 200a illustrated in FIG. 2 includes a first conductive layer 100 and a dielectric layer 120. The first conductive layer 100 and the dielectric layer 120 have been described with reference to the semiconductor structure 200 of FIG. 1.

The second crystallized seed layer 130 and a second conductive layer 140 may be sequentially provided on the dielectric layer 120. The second crystallized seed layer 130 may be provided in a second portion between the second conductive layer 140 and the dielectric layer 120. The second crystallized seed layer 130 may function as a seed for helping crystallization of the dielectric layer 120 of the semiconductor structure 200a when the dielectric layer 120 is heat treated. The second crystallized seed layer 130 may contribute to decreasing the crystallization temperature of the dielectric layer 120 and increasing the dielectric constant of the dielectric layer 120. The dielectric constant of the dielectric layer 120 may be increased to 60 or more when the dielectric layer 120 is crystallized. The second crystallized seed layer 130 may be a material layer that has the same crystal structure as that of the dielectric layer 120 when oxidized to lower the crystallization temperature of the dielectric layer 120.

The second crystallized seed layer 130 may include a similar material as that of the first crystallized seed layer 110 of the semiconductor structure 200 illustrated in FIG. 1. For example, the second crystallized seed layer 130 may be a niobium layer. The second conductive layer 140 in the semiconductor structure 200a is the same as the second conductive layer 140 of the semiconductor structure 200.

In some embodiments, the first conductive layer 100, the dielectric layer 120, the second crystallized seed layer 130, and the second conductive layer 140 may form a capacitor. The second crystallized seed layer 130 may be partially included in the dielectric layer 120 when the dielectric layer 120 is heat treated in the subsequent process.

Referring now to FIG. 3, a cross-section of a semiconductor structure 200b according to some embodiments of the present general inventive concept will be discussed. As illustrated in FIG. 3, the semiconductor structure 200b has features of the semiconductor structure 200 and the semiconductor structure 200a. In other words, the semiconductor structure 200b illustrated in FIG. 3 is similar to the semiconductor structures 200 and 200a, except that the first crystallized seed layer 110 is formed on the first conductive layer 100, and the second crystallized seed layer 130 is formed on the dielectric layer 120.

The semiconductor structure 200b may include a first conductive layer 100. The first conductive layer 100 of the semiconductor structure 200b is similar to the first conductive layer 100 of the semiconductor structure 200. A first crystallized seed layer 110 may be provided on the first conductive layer 100. The first crystallized seed layer 110 may be provided on a first portion between the first conductive layer 100 and a dielectric layer 120. The first crystallized seed layer 110 of the semiconductor structure 200b is similar to the crystallized seed layer 110 of the semiconductor structure 200.

The dielectric layer 120 is provided on the first crystallized seed layer 110. The dielectric layer 120 is similar to the dielectric layers 120 of the semiconductor structures 200 and 200a. A second crystallized seed layer 130 and a second conductive layer 140 are sequentially provided on the dielectric layer 120. The second crystallized seed layer 130 is provided on a second portion between the second conductive layer 140 and the dielectric layer 120. The second crystallized seed layer 130 and the second conductive layer 140 are respectively similar to the second crystallized seed layer 130 and the second conductive layer 140 of the semiconductor structure 200a.

In some embodiments, the first conductive layer 100, the first crystallized seed layer 110, the dielectric layer 120, the second crystallized seed layer 130, and the second conductive layer 140 may form a capacitor. Each of the first crystallized seed layer 110 and second crystallized seed layer 130 may be partially included in the dielectric layer 120 when the dielectric layer 120 is heat treated in the subsequent process.

Various processing steps in the fabrication of semiconductor structures and processing steps for heat treating a dielectric layer will now be discussed with respect to FIGS. 4 through 8. These embodiments may be performed individually or in combination without departing from the scope of embodiments discussed herein.

Referring first to FIG. 4, a flowchart illustrating processing steps in the fabrication of semiconductor structures illustrated in FIG. 1 and processing steps for heat treating a dielectric layer in accordance with some embodiments of the inventive concept will be discussed. As illustrated in FIG. 4, operations begin by forming a first conductive layer 100 of the semiconductor structure 200 illustrated in FIG. 1 (block 300). The first conductive layer 100 may be any of the material layers that have been described with reference to the semiconductor structures 200, 200a, and 200b illustrated in FIGS. 1 through 3. The first conductive layer 100 may be formed by sputtering, chemical vapor deposition (CVD), or atomic layer deposition (ALD).

The first crystallized seed layer 110 illustrated in FIG. 1 is formed on the first conductive layer 100 (block 302). The first crystallized seed layer 110 may be a niobium layer, as discussed above with reference to the semiconductor structure 200 of FIG. 1. The first crystallized seed layer 110 may be formed by sputtering, CVD, or ALD. The first crystallized seed layer 110 may have a thickness of about 10 through about 100 Å.

In some embodiments, the first crystallized seed layer 110 may be a niobium layer. The niobium layer may be formed by performing CVD using a precursor compound containing niobium. The precursor compound containing niobium may be an alkoxide precursor compound such as Nb(OMe)₅, Nb(OEt)₅, or Nb(OBu)₅, Nb[N CH_{3 2}]₅; or an amide precursor compound such as Nb[N(CH₃)₂]₅, (NtBu)Nb(NEtMe)₃, or (NtBu)Nb(NEt₂)₂ where Me represents methyl, Et represents ethyl, and Bu represents butyl.

The dielectric layer 120 is formed on the first crystallized seed layer 110 as illustrated in FIG. 1 (block 304). The dielectric layer 120 may be any of the material layers that have been discussed above with reference to the semiconductor structure 200 of FIG. 1. The dielectric layer 120 may be formed by sputtering, CVD, or ALD.

After the first crystallized seed layer 110 and the dielectric layer 120 are formed, the dielectric layer 120 is heat treated to be crystallized (block 306). The heat treatment process may be a furnace heat treatment process, a rapid heat treatment process, an ultraviolet heat treatment process, or a plasma heat treatment process, and may be performed under an oxygen, nitrogen, or air atmosphere. During the heat treatment process for the dielectric layer 120, the first crystallized seed layer 110 helps crystallization of the dielectric layer 120. Thus, due to the first crystallized seed layer 110, the heat treatment process for the dielectric layer 120 may be performed at a low temperature, for example, a temperature of about 575° C. When the dielectric layer 120 is heat treated, the first crystallized seed layer 110 may be partially included in the dielectric layer 120.

After the heat treatment process for the dielectric layer 120 is performed, the second conductive layer 140 is formed on the dielectric layer 120 as illustrated in FIG. 1 (block 308). The second conductive layer 140 may be any of the material layers that have been discussed above with reference to the semiconductor structure 200 of FIG. 1. The second conductive layer 140 may be formed by sputtering, CVD, or ALD.

Subsequently, if needed, the dielectric layer 120 may be further heat treated after the second conductive layer 140 is formed (this operation is not shown). If the dielectric layer 120 is further heat treated, the dielectric layer 120 may be further crystallized.

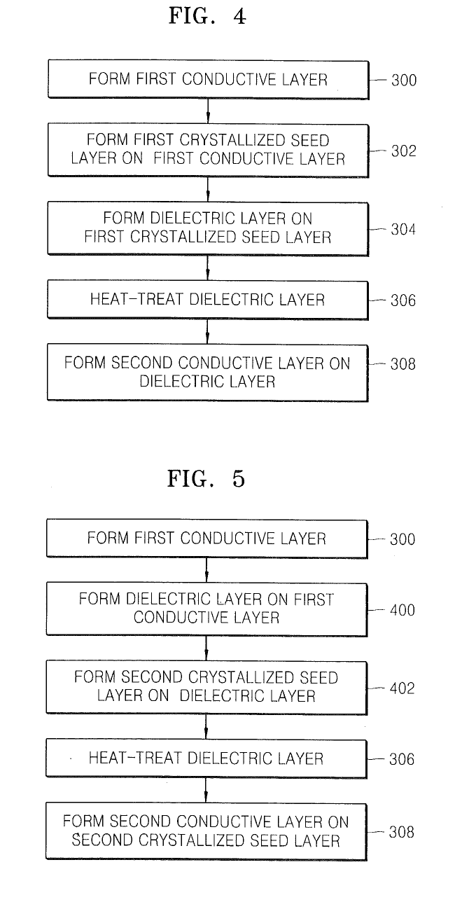

Referring now to FIG. 5, a flowchart illustrating processing steps in the fabrication of semiconductor structures illustrated in FIG. 2 and processing steps of heat treating a dielectric layer according to some embodiments of the present inventive concept. As illustrated in FIG. 5, the method is similar to details discussed above with respect to FIG. 4, except that the first crystallized seed layer 110 is not formed on the first conductive layer 100, and the second crystallized seed layer 130 is formed on the dielectric layer 120 and then the dielectric layer 120 is heat treated.

For example, the first conductive layer 100 of the semiconductor structure 200a illustrated in FIG. 2 is formed (block 300). The first conductive layer 100 may be the same material layer as discussed above with respect to FIG. 4, and may be formed using the similar methods.

The dielectric layer 120 is formed on the first conductive layer 100 as illustrated in FIG. 2 (block 400). The dielectric layer 120 may be any of the material layers that have been discussed above with reference to the semiconductor structure 200 of FIG. 2. The dielectric layer 120 may be formed by sputtering, CVD, or ALD.

The second crystallized seed layer 130 is formed on the dielectric layer 120 (block 402). The second crystallized seed layer 130 may be a niobium layer as discussed above with reference to the semiconductor structure 200 of FIG. 2. The second crystallized seed layer 130 and the first crystallized seed layer 110 may be formed of the same material. If the second crystallized seed layer 130 is a niobium layer, the precursors described above may be used. The second crystallized seed layer 130 may be formed by sputtering, CVD, or ALD. The second crystallized seed layer 130 may be formed to a thickness of 10 through 100 Å.

After the dielectric layer 120 and the second crystallized seed layer 130 are formed, the dielectric layer 120 is heat treated to be crystallized (block 306). Similar to embodiments discussed above, the heat treatment process may be a furnace heat treatment process, a rapid heat treatment process, an ultraviolet heat treatment process, or a plasma heat treatment process, and may be performed under an oxygen, nitrogen, or air atmosphere. During the heat treatment process for the dielectric layer 120, the second crystallized seed layer 130 helps crystallization of the dielectric layer 120. Thus, due to the second crystallized seed layer 130, the heat treatment process for the dielectric layer 120 may be performed at a low temperature, for example, a temperature of about 575° C. When the dielectric layer 120 is heat treated, the second crystallized seed layer 130 may be partially included in the dielectric layer 120.

After the heat treatment process for the dielectric layer 120 is performed, the second conductive layer 140 is formed on the second crystallized seed layer 130 as illustrated in FIG. 2 (block 308). The second conductive layer 140 may be any of the material layers that have been discussed above with reference to the semiconductor structure 200a of FIG. 2. The second conductive layer 140 may be formed using the similar methods.

Subsequently, if needed, the dielectric layer 120 may be further heat treated after the second conductive layer 140 is formed (not shown). If the dielectric layer 120 is further heat treated, the dielectric layer 120 may be further crystallized.

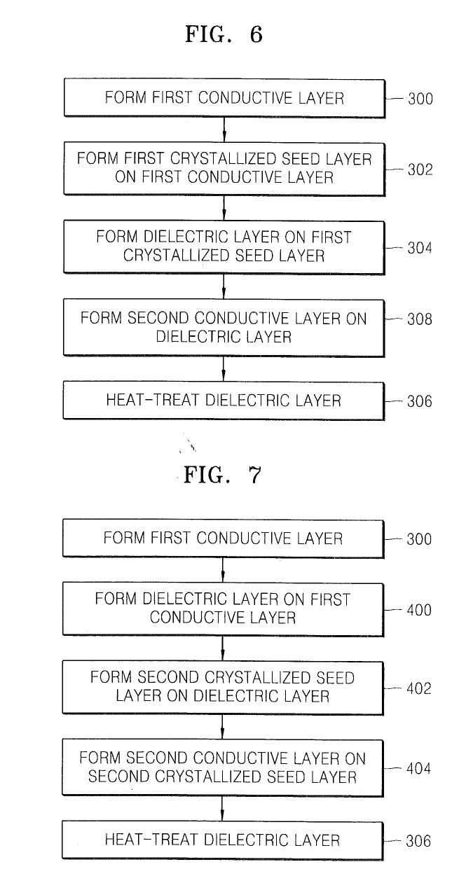

Referring now to FIG. 6, a flowchart illustrating processing steps in the fabrication of semiconductor structures of FIG. 1 and processing steps in heat treating a dielectric layer according to some embodiment of the present inventive concept. As illustrated in FIG. 6, the methods illustrated in FIG. 6 are similar to those discussed above with respect to FIG. 4, except that the dielectric layer 120 is heat treated after the second conductive layer 140 is formed on the dielectric layer 120.

For example, as discussed above with respect to the semiconductor structure 200 of FIG. 1 and the methods according embodiments discussed above, the first conductive layer 100, the first crystallized seed layer 110, and the dielectric layer 120 are sequentially formed on the first layer (blocks 300, 302, and 304). The first conductive layer 100, the first crystallized seed layer 110, and the dielectric layer 120 may be any of the material layers and may be formed using the methods discussed above.

As illustrated in the semiconductor structure 200 of FIG. 1, the second conductive layer 140 is formed on the dielectric layer 120 (block 308). The second conductive layer 140 may be any of the material layers described in the first and second embodiments and may be performed using the methods described in the first and second embodiments.

After the first crystallized seed layer 110, the dielectric layer 120, and the second conductive layer 140 are formed, the dielectric layer 120 is heat treated to be crystallized (block 306). Similar to embodiments discussed above, the heat treatment process may be a furnace heat treatment process, a rapid heat treatment process, an ultraviolet heat treatment process, or a plasma heat treatment process, and may be performed under an oxygen, nitrogen, or air atmosphere. During the heat treatment process for the dielectric layer 120, the first crystallized seed layer 110 helps crystallization of the dielectric layer 120. Thus, due to the first crystallized seed layer 110, the heat treatment process for the dielectric layer 120 may be performed at a low temperature, for example, a temperature of about 575° C. When the dielectric layer 120 is heat treated, the first crystallized seed layer 110 may be partially included in the dielectric layer 120.

Referring now to FIG. 7, a flowchart illustrating processing steps in the fabrication of the semiconductor structure illustrated in FIG. 2 and processing steps for heat treating a dielectric layer according to some embodiments of the present general inventive concept will be discussed. As illustrated in FIG. 7, the method of forming the semiconductor structure of FIG. 2 and the method of heat treating a dielectric layer of FIG. 7 is similar to the methods discussed above with respect to the semiconductor structure of FIG. 2, except that the dielectric layer 120 is heat treated after the second conductive layer 140 is formed on the dielectric layer 120.

For example, as discussed above with reference to the semiconductor structure 200a of FIG. 2 and related methods, the first conductive layer 100, the dielectric layer 120, and the second crystallized seed layer 130 may be sequentially formed on a first layer (blocks 300, 400, and 402). The first conductive layer 100, the dielectric layer 120, and the second crystallized seed layer 130 may include the material layer discussed above and may be formed using the methods described.

As illustrated with reference to the semiconductor structure 200a of FIG. 2, the second conductive layer 140 is formed on the second crystallized seed layer (block 404). The second conductive layer 140 may be any of the material layers discussed above and may be formed using the related methods.

After the dielectric layer 120, the second crystallized seed layer 130, and the second conductive layer 140 are formed, the dielectric layer 120 is heat treated to be crystallized (block 306). Similar to embodiments discussed above, the heat treatment process may be a furnace heat treatment process, a rapid heat treatment process, an ultraviolet heat treatment process, or a plasma heat treatment process, and may be performed under an oxygen, nitrogen, or air atmosphere. During the heat treatment process for the dielectric layer 120, the second crystallized seed layer 130 helps crystallization of the dielectric layer 120. Thus, due to the second crystallized seed layer 130, the heat treatment process for the dielectric layer 120 may be performed at a low temperature, for example, a temperature of about 575° C. When the dielectric layer 120 is heat treated, the second crystallized seed layer 130 may be partially included in the dielectric layer 120.

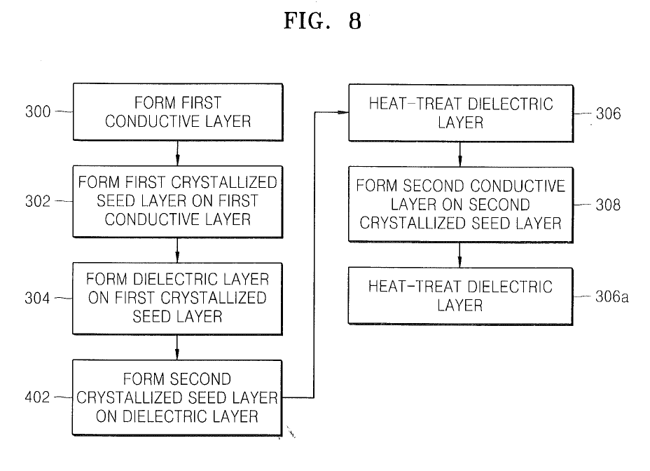

Referring now to FIG. 8, a flowchart illustrating processing steps in the fabrication of semiconductor structures illustrated in FIG. 3 and processing steps for heat treating a dielectric layer according to some embodiments of the inventive concept will be discussed. As illustrated in FIG. 8, the method of forming the semiconductor structure of FIG. 3 and a method of heat treating a dielectric layer may be similar to the embodiments discussed above, except that the dielectric layer 120 is heat treated after the first crystallized seed layer 110 is formed and then the second crystallized seed layer 130 is formed on the dielectric layer 120. Thus, embodiments illustrated in FIG. 8 are a combination of different embodiments discussed above.

For example, as discussed above with reference to the semiconductor structures 200 and 200b of FIGS. 1 and 3, the first conductive layer 100, the first crystallized seed layer 110, and the dielectric layer 120 may be sequentially formed on a first layer (blocks 300, 302, 304). The first conductive layer 100, the first crystallized seed layer 110, and the dielectric layer 120 may be any of the material layers discussed with respect to embodiments above and may be formed using the related methods.

As illustrated in the semiconductor structures 200a and 200b of FIGS. 2 and 3, the second crystallized seed layer 130 is formed on the dielectric layer 120 (block 402). The second crystallized seed layer 130 may be any of the material layers discussed above and may be formed using the related methods.

After the first crystallized seed layer 110, the dielectric layer 120, and the second crystallized seed layer 130 are formed, the dielectric layer 120 is heat treated to be crystallized (block 306). The dielectric layer 120 may be heat treated using the same method as described in the first through fourth embodiments. During the heat treatment process for the dielectric layer 120, the first crystallized seed layer 110 and the second crystallized seed layer 130 help crystallization of the dielectric layer 120. Thus, due to the first crystallized seed layer 110 and the second crystallized seed layer 130, the heat treatment process for the dielectric layer 120 may be performed at a low temperature, for example, a temperature of about 575° C. When the dielectric layer 120 is heat treated, the first crystallized seed layer 110 and the second crystallized seed layer 130 may be partially included in the dielectric layer 120.

After the dielectric layer 120 is heat treated, as illustrated in FIGS. 2 and 3, the second conductive layer 140 is formed on the second crystallized seed layer 130 (block 308). The second conductive layer 140 may be any of the material layers described with reference to the semiconductor structures 200a and 200b of FIGS. 2 and 3. The second conductive layer 140 may be formed using the methods described with respect to embodiments discussed above.

Subsequently, after the second conductive layer 140 is formed, the dielectric layer 120 is further heat treated (block 306a). The operations of block 306a may be the same as the operations of block 306. By performing the operations of block 306a, the dielectric layer 120 may be further crystallized.

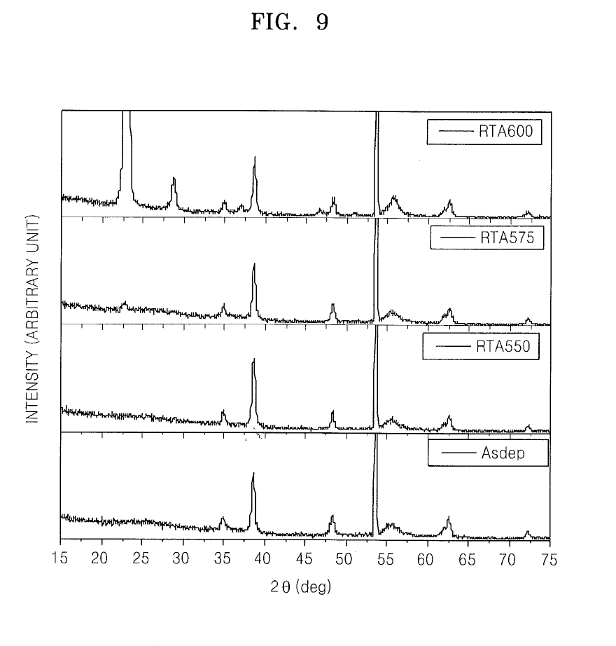

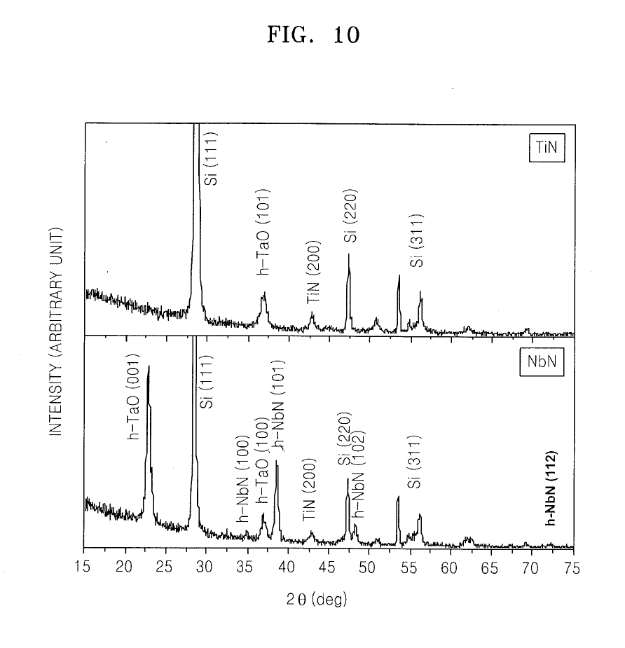

A degree of crystallinity of a dielectric layer according to the heat treatment temperature for the dielectric layer in accordance with some embodiments will now be discussed. Referring first to FIG. 9, a graph showing X-ray peaks to illustrate a degree of crystallinity of a dielectric layer according to a heat treatment temperature for the dielectric layer in accordance with some embodiments will be discussed. As illustrated in FIG. 9, the graph shows X-ray peaks obtained by irradiating X rays onto samples obtained by forming a niobium nitride layer, a niobium layer, and a tantalum oxide layer on a silicon substrate and then heat treating the tantalum oxide layer at various temperatures. That is, the silicon substrate is used as a first layer, the niobium nitride layer is used as a first conductive layer, the niobium layer is used as a first crystallized seed layer, and the tantalum oxide layer is used as a dielectric layer.

The heat treatment for the dielectric layer may be a rapid heat treatment process. X-rays are irradiated to a sample (Asdepo) including the tantalum oxide layer that is not heat treated, a sample (RTA 550) including the tantalum oxide layer that is rapidly heat treated at a temperature of 550° C., a sample (RTA 575) including the tantalum oxide layer that is rapidly heat treated at a temperature of 575° C., and a sample (RTA 600) including the tantalum oxide layer that is rapidly heat treated at a temperature of 600° C.

A tantalum oxide layer having a hexagonal crystal structure has an X-ray peak at around 22.5° C. Referring to FIG. 9, the sample including the tantalum oxide layer that is rapidly heat treated at a temperature of 575° C. has an X-ray peak at around 22.5° C. The sample including the tantalum oxide layer that is rapidly heat treated at a temperature of 600° C. also has an X-ray peak at around 22.5° C. Although conventionally a tantalum oxide layer having a hexagonal crystal structure has an X-ray peak at around 22.5° C. at a temperature of 700° C. or higher, the samples according to embodiments of the present inventive concept have the X-ray peak of the tantalum oxide layer having a hexagonal crystal structure at a temperature lower than 700° C., for example, 575° C. Thus, it can be seen that the heat treatment process can be performed at a relatively low temperature.

Referring now to FIG. 10, a graph showing X-ray peaks to illustrate a degree of crystallinity of a dielectric layer according to a first conductive layer at a constant heat treatment temperature in accordance with some embodiments will be discussed. In particular, FIG. 10 illustrates a graph showing X-ray peaks obtained by irradiating X rays onto samples obtained by forming either a titanium nitride layer or niobium nitride layer, a niobium layer, and a tantalum oxide layer on a silicon substrate and then heat treating the tantalum oxide layer at a temperature of 600° C. That is, the silicon substrate is used as a first layer, the titanium nitride layer or the niobium nitride layer is used as a first conductive layer, the niobium layer is used as a first crystallized seed layer, and the tantalum oxide layer is used as a dielectric layer. The heat treatment for the dielectric layer may be a rapid heat treatment process.

Referring to FIG. 10, X-ray peaks at around 22.5° C. and around 34° C. are observed. As described above, in general, a tantalum oxide layer having a hexagonal crystal structure has an X-ray peak at around 22.5° C. When the first conductive layer is a niobium nitride layer, the X-ray peak appears at around 22.5° C., and when the first conductive layer is a titanium nitride layer, the X-ray peak appears at around 34° C. Thus, it can be seen that when the dielectric layer is heat treated at a temperature of 600° C., the X-ray peak of the tantalum oxide layer having a hexagonal crystal structure is clearly observed, and varies according to a first conductive layer. The variance in location of the X-ray peak indicates the tantalum oxide layer has various degrees of crystallinity.

Semiconductor devices including semiconductor structures in accordance with some embodiments will now be discussed. Referring now to FIG. 11, a semiconductor device 600 including the semiconductor structure 200b of FIG. 3 in accordance with some embodiments of the present general inventive concept will be discussed. As illustrated, the semiconductor device 600 of FIG. 11 includes the semiconductor structure 200b of FIG. 3. However, the semiconductor structures 200 and 200a may also be included in the semiconductor device 600 without departing from the scope of the present inventive concept.

The semiconductor device 600 includes an impurity region 515 in a semiconductor substrate 510, for example, a silicon substrate. The impurity region 515 may be a p-type impurity region or n-type impurity region, according to a conductivity type of the silicon substrate. An insulating layer 530, for example, a silicon oxide layer may be formed on the semiconductor substrate 510. Contact holes 520 and 535 may contact the semiconductor substrate 510 and may be formed in the insulating layer 530. A conductive plug 525 may fill the contact hole 520. The conductive plug 525 may include various conductive materials, for example, tungsten, an impurity-doped polysilicon, aluminum, or copper.

The semiconductor structure 200b may fill the contact hole 535 and on the insulating layer 530. The semiconductor structure 200b may be a capacitor. The first conductive layer 100 may be formed on an inner wall of the contact hole 535. The first crystallized seed layer 110, the dielectric layer 120, the second crystallized seed layer 130, and the second conductive layer 140 may be sequentially formed on the first conductive layer 100. The first crystallized seed layer 110, the dielectric layer 120, the second crystallized seed layer 130, the second conductive layer 140, and the first conductive layer 100 may be any of the material layers that have been described in the previous embodiments. The semiconductor structure 200b may also be used in other portions of the semiconductor device 600 of FIG. 1.

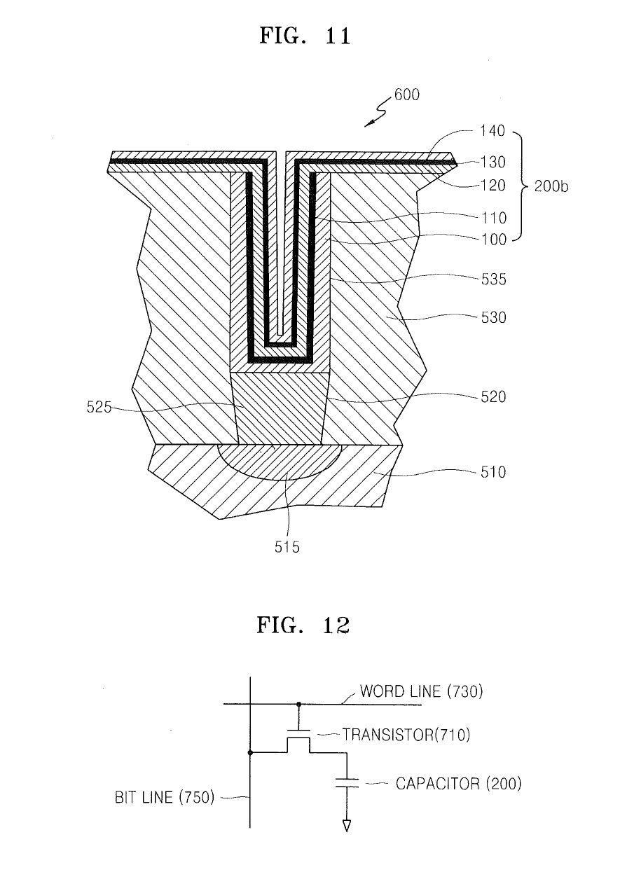

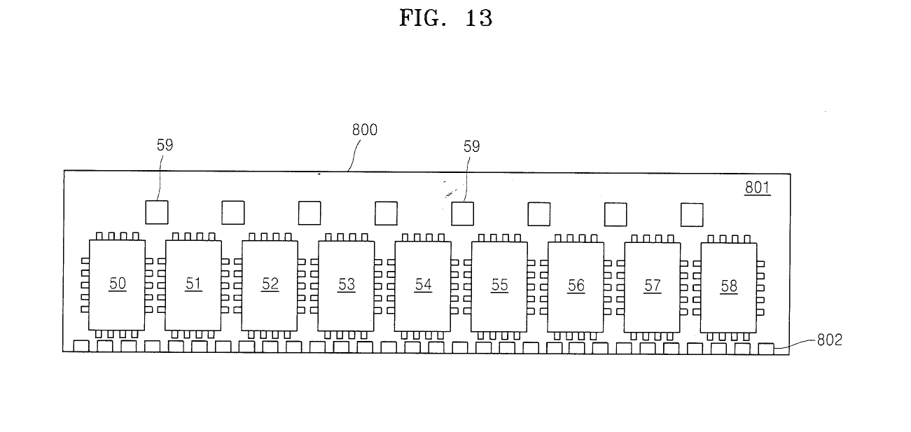

Example uses of embodiments discussed herein will now be discussed with respect to FIGS. 12 through 15. The semiconductor structures 200, 200a, and 200b may be used as a capacitor. Such a capacitor may be used in a semiconductor device, for example, a dynamic random access memory (DRAM) device, or a logic device. Referring first to FIG. 12, a diagram illustrating the semiconductor structure 200 used as a capacitor will be discussed. As illustrated, FIG. 12 is a circuit diagram of a unit cell of a DRAM device including a capacitor according to some embodiments of the present general inventive concept. Although a unit cell of a DRAM device may have various structures, the unit cell according to embodiments illustrated in FIG. 12 includes a transistor 710 and a capacitor 730. The transistor 710 is connected to a word line 730. The transistor includes a source region and a drain region. The bit line 750 is connected to either the source region or the drain region. The unconnected region among the source region and the drain region is connected to the semiconductor structure 200. That is, semiconductor structures according to some embodiments of the present general inventive concept are used as a capacitor of a DRAM device.

A semiconductor device according to some embodiments of the present general inventive concept, for example, a DRAM device or a logic device may be variously used. When the semiconductor device according to some embodiments, for example, a DRAM device or a logic device is packaged, a DRAM chip or a logic chip is obtained. The DRAM chip and the logic chip may be used in various applications, some of which will be described in detail herein.

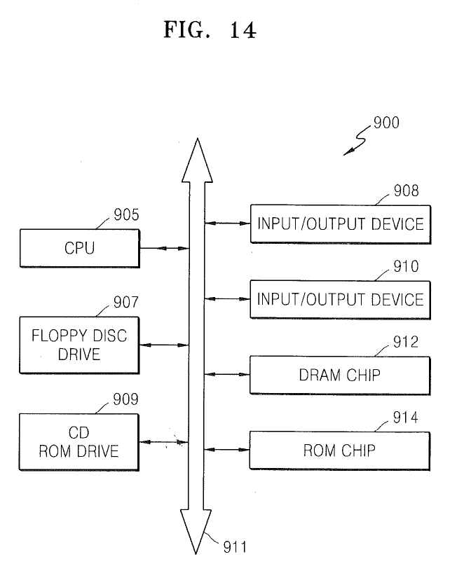

Referring now to FIG. 13, a plan view of a memory module 800 including a DRAM chip according to some embodiments of the present general inventive concept will be discussed. As illustrated in FIG. 13, DRAM chips 50-58 are obtained by packaging semiconductor devices according to embodiments of the present invention. The DRAM chips 50-58 may be used in the memory module 800. In the memory module 800, the DRAM chips 50-58 may be attached to a module substrate 801. In the memory module 800, a connection portion 802 is located on one side of the module substrate 801 and is inserted into a socket of a mother board, and a ceramic decoupling capacitor 59 is disposed on the module substrate 801. The structure of the memory module 800 may not be limited to FIG. 13.

Referring now to FIG. 14, a block diagram of an electronic system 900 including a DRAM chip according to some embodiments of the present general inventive concept will be discussed. As illustrated in FIG. 14, the electronic system 900 according to some embodiments may be a computer. The electronic system 900 includes a central processing unit (CPU) 905; a peripheral device such as a floppy disc drive 907 or a CD ROM drive 909; input and output devices 908 and 910, a DRAM chip 912, and a read only memory (ROM) chip 914. These components send or receive control signals or data by using a communication channel 911. The DRAM chip 912 may be replaced with the memory module 800 including the DRAM chips 50-58 illustrated in FIG. 13.

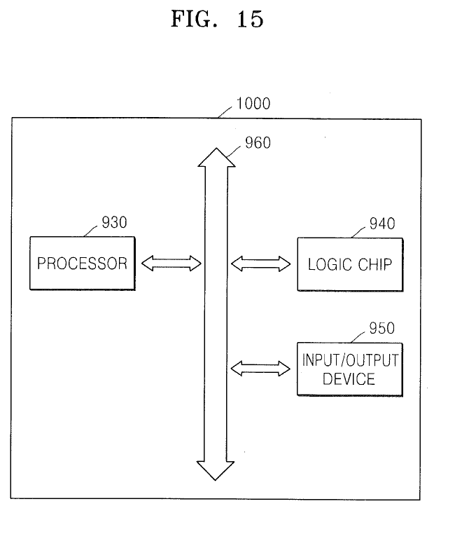

Referring now to FIG. 15, a block diagram of an electronic system 1000 including a logic chip according to some embodiment of the present general inventive concept will be discussed. Referring to FIG. 15, the electronic system 1000 may include a processor 930, an input/output device 950, and a logic chip 940, which data-communicate with each other by a bus 960. The processor 930 performs a program and controls the electronic system 1000. The input/output device 950 may be used to input or output data of the electronic system 1000. The electronic system 1000 may be connected to an external device, such as a personal computer or network through the input/output device 950 and may exchange data with the external device. The logic chip 940 may process cords and data for operating the processor 310.

The electronic system 1000 may be used in various electronic control device requiring the logic chip 940, for example, in mobile phones, MP3 players, navigation devices, solid state disks (SSD), and household appliances.

Semiconductor structures according to embodiments discussed above may include a dielectric layer on, under, or on and under a crystallized seed layer. The dielectric layer may be a tantalum oxide layer, a niobium oxide layer, or a composite layer including a tantalum oxide layer and a niobium oxide layer. The crystallized seed layer may be a niobium layer. Due to the crystallized seed layer, the dielectric layer may be crystallized by a low-temperature heat treatment. When the dielectric layer is crystallized by low-temperature heat treatment, the dielectric constant of the dielectric layer may be increased and leakage characteristics of the dielectric layer may be improved.

While the inventive concept has been particularly shown and described with reference to exemplary embodiments thereof, it will be understood that various changes in form and details may be made therein without departing from the spirit and scope of the following claims.

1. A semiconductor structure comprising:
a first conductive layer;
a dielectric layer on the first conductive layer;
a second conductive layer on the dielectric layer; and
a crystallized seed layer in at least one of a first portion of the semiconductor structure between the first conductive layer and the dielectric layer and a second portion of the semiconductor structure between the dielectric layer and the second conductive layer.

2. The semiconductor structure of claim 1, wherein the crystallized seed layer comprises a niobium layer.

3. The semiconductor structure of claim 1, wherein the dielectric layer comprises one of a tantalum oxide layer, a niobium oxide layer and a composite layer including a tantalum oxide layer and a niobium oxide layer.

4. The semiconductor structure of claim 1, wherein when oxidized, the crystallized seed layer has a similar crystal structure to a crystal structure of the dielectric layer.

5. The semiconductor structure of claim 4, wherein the crystallized seed layer comprises a niobium layer and wherein the dielectric layer comprises one of a tantalum oxide layer, a niobium oxide layer and a composite layer comprising a tantalum oxide layer and a niobium oxide layer.

6. The semiconductor structure of claim 1, wherein each of the first conductive layer and the second conductive layer comprises at least one of a metal nitride layer, a noble metal layer, a noble metal oxide layer, a metal silicide layer, an impurity-doped silicon layer and a metal layer.

7. The semiconductor structure of claim 1, wherein at least one of the first conductive layer and the second conductive layer is a metal nitride layer that has a similar crystal structure as a crystal structure of the dielectric layer.

8. The semiconductor structure of claim 7, wherein one of the first conductive layer and the second conductive layer is a niobium nitride layer or a tantalum nitride layer.

9. A semiconductor structure comprising:
a first conductive layer that includes metal nitride;
a dielectric layer on the first conductive layer, wherein the dielectric layer is one of a tantalum oxide layer, a niobium oxide layer and a composite layer including a tantalum oxide layer and a niobium oxide layer;
a second conductive layer on the dielectric layer, wherein the second conductive layer is a metal nitride layer; and
a crystallized seed layer including niobium and is in at least one of a first portion of the semiconductor structure between the first conductive layer and the dielectric layer, and a second portion of the semiconductor structure between the dielectric layer and the second conductive layer.

10. The semiconductor structure of claim 9, wherein the metal nitride layer comprises one of a tantalum nitride layer and a niobium nitride layer.

11. A capacitor comprising:
a first conductive layer;
a dielectric layer on the first conductive layer;
a second conductive layer on the dielectric layer; and
a crystallized seed layer in at least one of a first portion of the capacitor between the first conductive layer and the dielectric layer, and a second portion of capacitor between the dielectric layer and the second conductive layer.

12. The capacitor of claim 11, wherein when oxidized, the crystallized seed layer has a same crystal structure as a crystal structure of the dielectric layer.

13. The capacitor of claim 12, wherein the crystallized seed layer comprises a niobium layer and wherein the dielectric layer comprises one of a tantalum oxide layer, a niobium oxide layer and a composite layer comprising a tantalum oxide layer and a niobium oxide layer.

14. The capacitor of claim 11, wherein the first conductive layer and the second conductive layer comprises one of a metal nitride layer, a noble metal layer, a noble metal oxide layer, a metal silicide layer, an impurity-doped silicon layer and a metal layer.

15. The capacitor of claim 11, wherein one of the first conductive layer and the second conductive layer is a metal nitride layer that has a similar crystal structure as a crystal structure of the dielectric layer.

16. The capacitor of claim 15, wherein one of the first conductive layer and the second conductive layer is a niobium nitride layer or a tantalum nitride layer.

17.-20. (canceled)
